(19) United States
(12) Patent Application Publication
(10) Pub. No.: US 2026/0040803 A1
(43) Pub. Date: Feb. 5, 2026

(54) DISPLAY APPARATUS, METHOD OF MANUFACTURING SAME AND ELECTRONIC DEVICE

(71) Applicant: Samsung Display Co., Ltd., Yongin-si, Gyeonggi-do (KR)

(72) Inventors: JUHEE KIM, Yongin-si (KR); CHEULJIN PARK, Yongin-si (KR); JUNHEE SON, Yongin-si (KR)

(21) Appl. No.: 19/212,459

(22) Filed: May 19, 2025

(30) Foreign Application Priority Data
Aug. 1, 2024 (KR) 10-2024-0102299

(51) Int. Cl. H10K 59/80

(52) U.S. Cl. CPC H10K 59/8794; H10K 59/8722

(57) ABSTRACT

A display apparatus is provided. The display apparatus includes a display panel that emits visible light, and a heat dissipation member that is provided on one surface of the display panel, wherein the heat dissipation member includes a base sheet, a cover that is provided to face a surface opposite to a surface, which faces the display panel, of surfaces of the base sheet, and a groove that is formed in the base sheet such that at least a fluid moves. The groove has a region in which a width of a portion farthest from the display panel is narrower than a width of a portion closest to the display panel based on a thickness direction of the base sheet.

### CROSS-REFERENCE TO RELATED APPLICATION

This application claims priority to and the benefit of Korean Patent Application No. 10-2024-0102299, filed on Aug. 1, 2024, in the Korean Intellectual Property Office, the entire disclosure of which is incorporated herein by reference.

### BACKGROUND

### 1. Field

One or more aspects of embodiments of the present disclosure relate to display apparatus(es), methods of manufacturing the same, and electronic devices.

### 2. Description of the Related Art

Electronic devices such as smart phones, tablet PCs, digital cameras, laptop computers, navigators, smart televisions and/or the like provide images to users and include display apparatus(es) for displaying the images. A display apparatus includes a display panel that generates and displays images and one or more suitable input devices.

For example, a display apparatus may include a display panel that generates an image through a plurality of light-emitting elements, and a heat dissipation member attached to a bottom of the display panel. The plurality of light-emitting elements of the display panel may display an image through power supplied from an external source. The plurality of light-emitting elements may display an image through applied power (by converting power into light energy), but some of the applied power (e.g., not converted into the light energy) may be lost to the surroundings (discharged to outside of the display panel) in the form of heat energy.

### SUMMARY

One or more aspects of embodiments of the present disclosure are directed toward display apparatus(es) having improved manufacturing convenience and heat dissipation characteristics, methods of manufacturing the same, and an electronic device. However, aspects of the present disclosure are not restricted to those set forth herein.

Additional aspects will be set forth in part in the description which follows and, in part, will be apparent from the description, or may be learned by practice of the presented embodiments of the disclosure.

According to one or more embodiments, a display apparatus includes a display panel that realizes (is configured to emit) visible light and a heat dissipation member that is provided on a (e.g., one) surface of the display panel. The heat dissipation member includes a base sheet having a first surface and a second surface, the second surface being opposite to the surface of the display panel, and a cover having a surface opposite to the first surface of the base sheet (e.g., that is provided to face a surface opposite to a surface, which faces the display panel, of surfaces of the base sheet). A groove is provided (that is formed) in the base sheet and is a fluid passage, such that at least a fluid moves, and has a first width region and a second width. The first width region is distal to the display panel based on a thickness direction of the base sheet, and is more narrow than the second width region that is proximal to the display panel based on the thickness direction of the base sheet. In other words, the grove has a region, in which a width of a portion farthest from the display panel is narrower than a width of a portion closest to the display panel based on a thickness direction of the base sheet.

In one or more embodiments, the groove may have a shape having (in which) a width gradually decreases along a depth direction thereof.

In one or more embodiments, the groove may have an inclined surface in at least one region of the base sheet.

In one or more embodiments, the groove may include symmetrical inclined surfaces.

In one or more embodiments, an angle formed between an extension line of the second surface, (e.g., facing the display panel, of the surfaces of the base sheet) and an inner surface of the groove may be equal to or less (smaller) than 90 degrees) (°).

In one or more embodiments, an angle formed between an extension line of the second surface, (e.g., facing the display panel, of the surfaces of the base sheet) and an inner surface of the groove may be in a range from 50° to 80°.

In one or more embodiments, a first adhesive layer may be provided in at least one region between the base sheet and the cover.

In one or more embodiments, the first adhesive layer may include a thermal adhesive and a first spacing region in a region corresponding to the groove, and the first spacing region may exclude the thermal adhesive.

In one or more embodiments, a plate may be coupled (provided to be connected) to the second surface, (e.g., opposite to a surface facing the cover, of the surfaces) of the base sheet.

In one or more embodiments, a second adhesive layer may be provided in at least one region between the base sheet and the plate.

In one or more embodiments, the second adhesive layer may include a thermal adhesive and a second spacing region in a region corresponding to the groove, and the second spacing region may exclude the thermal adhesive.

In one or more embodiments, a third adhesive layer may be provided between the plate and the display panel.

In one or more embodiments, the base sheet may include a flexible material.

In one or more embodiments, the base sheet may include a polymer-based material.

In one or more embodiments, the display panel may include an organic light-emitting element.

According to one or more embodiments, a method for manufacturing a display apparatus includes providing a display panel that is configured to emit (realizes) visible light, providing a heat dissipation member, and coupling or attaching the display panel to the heat dissipation member. The heat dissipation member may include a base sheet having a first surface and a second surface, the second surface opposite to a surface of the display panel, and a cover having a surface opposite to the first surface (e.g., that is provided to face a surface opposite to a surface, which faces the display panel, of surfaces of the base sheet). A groove is provided (that is formed) in the base sheet that is a fluid passage, such that at least a fluid moves, and has a first width region and a second width region, the first width region is distal to the display panel based on a thickness direction of the base sheet, and more narrow than the second width region that is proximal to the display panel based on the thickness direction of the base sheet. In other words, the grove has a region, in which a width of a portion farthest from the display panel is narrower than a width of a portion closest to the display panel based on a thickness direction of the base sheet.

In one or more embodiments, the providing the heat dissipation member may include forming the groove in a surface (the first surface and/or the second surface) of the base sheet by (through a process) using a mold.

In one or more embodiments, the mold may include a cutting die for punching.

In one or more embodiments, the providing the heat dissipation member may include, (e.g., after) forming adhesive layers on the first (e.g., one) surface and the second (e.g., opposite) surface of the base sheet, and forming the groove by using the mold.

In one or more embodiments, the providing the heat dissipation member may include adhering a plate after forming the groove.

According to one or more embodiments, an electronic device includes a display module, a processor, a memory and a power module, wherein the display module includes a display panel configured to emit (that realizes) visible light and a heat dissipation member that is provided on a (e.g., one) surface of the display panel. The heat dissipation member includes a base sheet having a first surface and a second surface, the second surface opposite to the surface of the display panel, and a cover having a surface opposite to the first surface (e.g., that is provided to face a surface opposite to a surface, which faces the display panel, of surfaces of the base sheet). A groove is provided (that is formed) in the base sheet that is a fluid passage (such that at least a fluid moves), and has a first width region and a second width region, the first width region is distal to the display panel based on a thickness direction of the base sheet, and more narrow than the second width region that is proximal to the display panel based on the thickness direction of the base sheet. In other words, the grove has a region, in which a width of a portion farthest from the display panel is narrower than a width of a portion closest to the display panel based on a thickness direction of the base sheet.

### BRIEF DESCRIPTION OF THE DRAWINGS

The accompanying drawings are included to provide a further understanding of the preceding and other aspects, features, and advantages of certain embodiments of the present disclosure and are incorporated in and constitute a part of this specification. The drawings illustrate example embodiments that will be more apparent from the following description taken in conjunction with the accompanying drawings, wherein:

FIG. 1 is a cross-sectional view schematically illustrating a display apparatus according to one or more embodiments of the present disclosure;

FIG. 2 is an enlarged view schematically illustrating an example of a part A in FIG. 1;

FIG. 3 is a diagram illustrating a modified example of FIG. 2;

FIG. 4 is a cross-sectional view schematically illustrating an example of the display apparatus of FIG. 1;

FIG. 5 is a cross-sectional view schematically illustrating an example of a cross-section taken along the line I-I′ of FIG. 1;

FIGS. 6-12 are cross-sectional views, each illustrating an example of a method for manufacturing a display apparatus according to one or more embodiments of the present disclosure;

FIG. 13 is a cross-sectional view illustrating an example of a cutting die used in manufacturing the display apparatus of FIG. 12;

FIG. 14 is a cross-sectional view illustrating an example of a cutting die used in manufacturing a display apparatus according to one or more embodiments of the present disclosure;

FIG. 15 is a cross-sectional view illustrating an example of a display apparatus manufactured by using a cutting die of FIG. 14;

FIG. 16 is a cross-sectional view illustrating an example of a cutting die used in manufacturing a display apparatus according to one or more embodiments of the present disclosure;

FIG. 17 is a cross-sectional view illustrating an example of a display apparatus manufactured by using the cutting die of FIG. 16;

FIG. 18 is a block diagram of an electronic device according to one or more embodiments of the present disclosure; and

FIG. 19 illustrates schematic views of individual electronic devices according to one or more embodiments of the present disclosure.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described herein, by referring to the figures, to explain aspects.

As used herein, the term “and/or” includes any and all combinations of one or more of the associated listed items. Expressions such as “at least one of,” “one of,” “selected from,” and “selected from among,” when preceding a list of elements, modify the entire list of elements and do not modify the individual elements of the list. For example, throughout the disclosure, the expressions “at least any one of X, Y, and Z” and “at least any one selected from among a group of X, Y, and Z” may be interpreted as one X, one Y, one Z, and/or a (e.g., any suitable) combination of two or more of X, Y, and Z (e.g., XYZ, XYY, YZ, ZZ).

Since the present disclosure can be modified in one or more suitable ways and can have one or more suitable embodiments, specific embodiments will be illustrated in the drawings and specifically described in the detailed description. The effects and features of the present disclosure and methods for achieving the same will be clearly understood by referring to embodiments to be described in detail herein along with the drawings. However, the present disclosure is not limited to the embodiments disclosed herein and may be implemented in one or more suitable forms.

In the following embodiments, terms such as “first” and “second” may be used to describe one or more suitable components, these terms are used not in a limiting sense but for the purpose of distinguishing one component from another component. Accordingly, a first component may be referred to as a second component without departing from the present disclosure.

In embodiments disclosed herein, a singular representation such as “a”, “an” and “the” may include a plural representation unless it represents a definitely different meaning from the context.

In embodiments disclosed herein, terms such as “comprising,” “comprise,” “comprises,” “includes,” “including,” “include,” “have,” “having,” or “has” should be understood that they are intended to indicate an existence of features or components, disclosed in this specification, and also it is not excluded in advance that one or more features or components are likewise utilized. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof. In this context, “consisting essentially of” indicates that any additional components will not materially affect the chemical, physical, optical or electrical properties of the display panel and/or electronic device.

In the embodiments disclosed herein, when a part such as a unit, area, component, and/or the like is said to be located on another part, (e.g. spatially relative terms such as “below” and “above”) it includes not only the case where the part is directly located on the another part, but also the case where other units, areas, components, and/or the like are interposed therebetween. The spatially relative term is intended to include different orientations in use, operation, and/or manufacture, in addition to the orientation depicted in the drawing. For example, if a device shown in the drawing is turned over, elements depicted as being positioned “below” other elements or features are positioned “above” the other elements or features. Hence, the term “below” may include both (e.g., simultaneously) upward and downward directions in one or more embodiments. Besides, the device may be oriented in other directions (e.g., rotated 90 degrees or in a different direction), and thus the spatially relative terms used herein are interpreted accordingly.

In the following embodiments, terms such as “connected” or “coupled” do not necessarily mean “two members being directly and/or fixedly connected or coupled,” unless otherwise specified within the context, and do not exclude the intervention of other members between the two members.

In the drawings, the sizes of components may be enlarged or exaggerated or reduced for convenience of explanation. For example, the size and/or thickness of each component illustrated in the drawings are illustrative for convenience of description, and the present disclosure is not necessarily limited thereto.

Unless otherwise defined, all terms including chemical, technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The term “may” will be understood to refer to “one or more embodiments of the present disclosure,” some of which include the described element and some of which exclude that element and/or include an alternate element. Similarly, alternative language such as “or” refers to “one or more embodiments of the present disclosure,” each including a corresponding listed item.

In this specification, phrases such as “on a plane,” and/or the like indicate viewing a target portion from the top, and the phrase “on a cross-section” indicates viewing a cross-section formed by vertically cutting a target portion from the side.

Hereinafter, a description will be given in detail of preferred embodiments disclosed herein, with reference to the accompanying drawings. For description with reference to the drawings, the same or equivalent components may be given the same reference numerals, and a redundant description thereof will not be provided.

### Display Apparatus

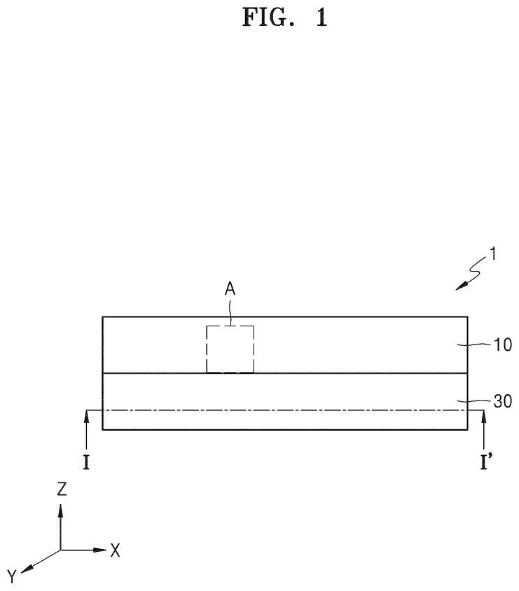

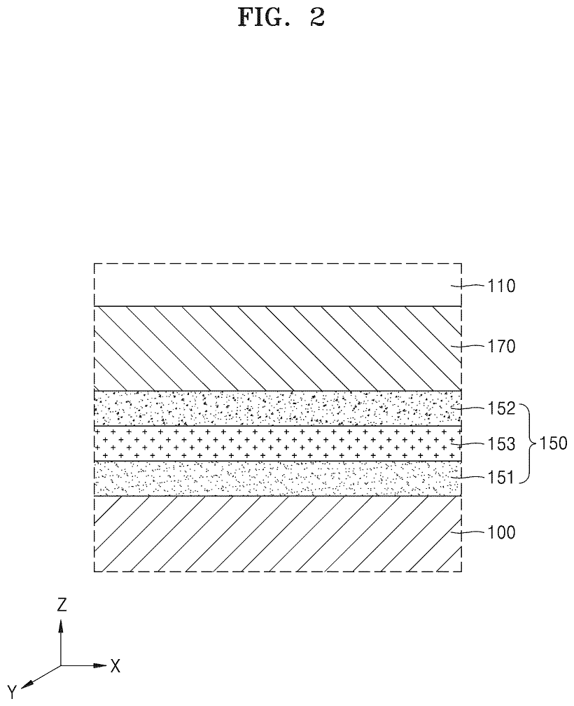

FIG. 1 is a cross-sectional view schematically illustrating a display apparatus according to one or more embodiments of the present disclosure, and FIG. 2 is an enlarged view schematically illustrating an example of a part A in FIG. 1.

Referring to FIG. 1, a display apparatus 1 according to one or more embodiments of the present disclosure may include a display area and a peripheral area. The peripheral area is defined outside the display area to surround the display area. One or more suitable wires and driving circuit parts may be located in the peripheral area and transmit electrical signals to be applied to the display area. The display apparatus 1 may provide a certain image by using light emitted from a plurality of pixels provided in the display area. In one or more embodiments, the display apparatus 1 may be bent, by including a bending region, in a partial region of the peripheral area.

The display apparatus 1 may be a display apparatus such as an organic light-emitting display (OLED) apparatus, an inorganic light-emitting display (or inorganic EL display) apparatus, or a quantum dot light-emitting display apparatus. Hereinafter, an organic light-emitting display apparatus will be described as an example. Examples of the display apparatus 1 may include one or more suitable types (kinds) of electronic devices such as mobile phones, laptop computers, smart watches, and/or the like.

The display apparatus 1 may include a display panel 10 that emits (realizes) visible light, and a heat dissipation member 30 provided on a surface of the display panel, opposite to one surface where the visible light is emitted (realized). For example, visible light may be emitted (realized) in one direction (an upward direction in FIG. 1) from an upper surface of the display panel 10 (e.g., an upper surface based on FIG. 1), and the heat dissipation member 30 may be provided on an opposite surface (e.g., a lower surface based on FIG. 1) to the surface, from which the visible light is emitted (realized), among surfaces of the display panel 10, and may be coupled or connected in a manner of being in contact with or bonded to the corresponding surface.

The display panel 10 may provide an image that can be recognized by a user and may include an organic light-emitting element on one surface where visible light is emitted (realized).

By virtue of specific configurations and steps to be described later, material costs and machining costs can be reduced, and a display apparatus 1 in which passages are freely machined and formed can be produced.

As illustrated in FIG. 2, the display panel 10 may include a display element 150 that is capable of emitting (e.g., realizing) (or is configured to emit) visible light to provide the visible light to the user. The display element 150 may be implemented as one or more suitable types (kinds) of display elements, and this embodiment is an example to describe a case where the display element 150 is an organic light-emitting element.

The display panel 10 will be described in more detail. The display panel 10 may include a substrate 100, a display element 150, an encapsulation member 170, and an optical functional layer 110.

The substrate 100 may be formed using one or more suitable materials. For example, the substrate 100 may be made of a transparent glass material including (e.g., containing) SiO₂ as its main component. In some embodiments, the substrate 100 may be formed of a transparent plastic material.

The display element 150 may be formed on the substrate 100 and may include a first electrode 151, a second electrode 152, and an intermediate layer 153. For example, the first electrode 151 may be formed on the substrate 100, the second electrode 152 may be formed on the first electrode 151, and the intermediate layer 153 may be formed between the first electrode 151 and the second electrode 152.

In some embodiments, a buffer layer may be further formed on the first electrode 151 and the substrate 100. The buffer layer may provide or define a flat surface on the substrate 100 and may block moisture and/or gas penetrating through the substrate 100.

The first electrode 151 may function as an anode and the second electrode 152 may function as a cathode. Of course, the order of these polarities may be reversed. When the first electrode 151 functions as an anode, the first electrode 151 may include (e.g., contain) ITO, IZO, ZnO, In₂O₃, and/or the like, which has a high work function. Additionally, depending on the purpose and design conditions, the first electrode 151 may further include a reflection film formed of Ag, Mg, Al, Pt, Pd, Au, Ni, Nd, Ir, Cr, Li, Yb, and/or Ca.

When the second electrode 152 functions as a cathode, the second electrode 152 may be formed of a metal such as Ag, Mg, Al, Pt, Pd, Au, Ni, Nd, Ir, Cr, Li, and/or Ca. Additionally, the second electrode 152 may contain ITO, IZO, ZnO, and/or In₂O₃ to enable light transmission.

The intermediate layer 153 has at least one organic light-emitting layer. In some embodiments, the intermediate layer 153 may optionally include at least one of a hole injection layer, a hole transport layer, an electron transport layer, and/or an electron injection layer, in addition to the organic light-emitting layer. When a voltage is applied to the first electrode 151 and the second electrode 152, visible light is generated from the intermediate layer 153, for example, from the organic light-emitting layer of the intermediate layer 153.

The encapsulation member 170 may be provided on the display element 150 to protect the display element 150. The encapsulation member 170 may protect the display element 150 from external impacts and reduce or suppress the penetration of external foreign substances, moisture, and/or the like.

The encapsulation member 170 may be formed in one or more suitable types (kinds). In one or more embodiments, the encapsulation member 170 may be made of a transparent glass material including (e.g., containing) SiO₂ as its main component. In one or more embodiments, the encapsulation member 170 may be formed of a plastic material through which light can be transmitted. In one or more embodiments, the encapsulation member 170 may be formed using an inorganic film or an organic film. In some embodiments, the encapsulation member 170 may be formed by stacking at least one (e.g., one or more) organic layers and at least one (e.g., one or more) inorganic layers, and optionally, may be formed by alternately stacking the organic layer(s) and the inorganic layer(s).

In one or more embodiments, the display panel 10 may provide an image in an upward direction, namely, toward the optical functional layer 110 based on FIG. 2. The optical functional layer 110 may include a base material and optical functional particles.

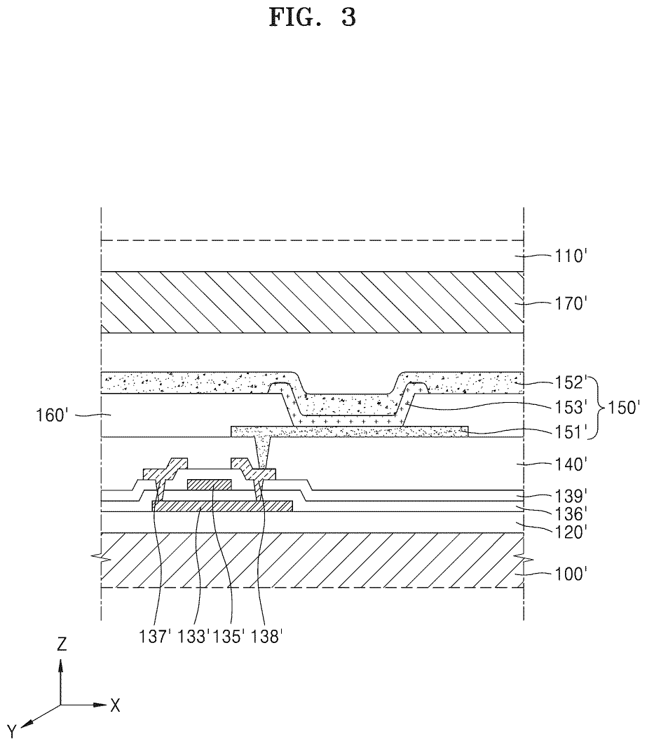

The display panel 10 may include a thin film transistor that transmits a signal, which is necessary to drive the display element 150, to the display element 150. This will be described in more detail with reference to FIG. 3.

FIG. 3 is a diagram illustrating a modified example of FIG. 2. Referring to FIG. 3, the display panel 10 may include a substrate 100′, a display element 150′, a thin film transistor, and an encapsulation member 170′.

The thin film transistor may include an active layer 133′, a gate electrode 135′, a source electrode 137′, and a drain electrode 138′. This will be explained in more detail. A buffer layer 120′ may be formed on the substrate 100′. The buffer layer 120′ is to suppress penetration of impurity elements through the substrate 100′ and provide a flat surface on a top of the substrate 100′, and may be formed of one or more suitable materials capable of or suitable for playing such roles. The buffer layer 120′ may also not be provided because it is an optional component.

The active layer 133′ may be provided as a certain pattern on the buffer layer 120′. The active layer 133′ may be formed of an inorganic semiconductor material such as silicon, may be formed of an organic semiconductor material as an optional embodiment, or may contain an oxide semiconductor material as another optional embodiment.

A gate insulating layer 136′ may be formed on the active layer 133′. The gate insulating layer 136′ may be formed of one or more suitable insulating materials, and may be formed using, for example, an oxide and/or a nitride.

A gate electrode 135′ may be formed on the gate insulating layer 136′ to correspond to a certain region of the active layer 133′. The gate electrode 135′ may be formed of a material with high conductivity. For example, the gate electrode 135′ may include (e.g., contain) Au, Ag, Cu, Ni, Pt, Pd, Al, and/or Mo, and may contain an alloy such as Al:Nd, Mo:W, and/or the like. However, this is just one example and the embodiment is not limited thereto and may be formed of one or more suitable materials.

An interlayer insulating layer 139′ may be formed to cover the gate electrode 135′. A source electrode 137′ and a drain electrode 138′ may be formed on the interlayer insulating layer 139′. The source electrode 137′ and the drain electrode 138′ may be formed to be in contact with a certain region of the active layer 133′.

A passivation layer 140′ may be formed to cover the source electrode 137′ and the drain electrode 138′. Although not illustrated, a separate insulating layer may further be formed on the passivation layer 140′ to planarize a thin film transistor.

In one or more embodiments, the display element 150′ may further include at least one (e.g., one or more) thin film transistors that are electrically connectible to the display element 150′, and may further include at least one (e.g., one or more) capacitors that are electrically connectible to the display element 150′ or the thin film transistors.

A first electrode 151′ may be formed on the passivation layer 140′. The first electrode 151′ may be electrically coupled or connected to one of the source electrode 137′ and the drain electrode 138′. For example, the first electrode 151′ may be coupled or connected to the drain electrode 138′.

A pixel-defining layer 160′ may be formed on the first electrode 151′ and may be formed to expose a certain area of the first electrode 151′.

An intermediate layer 153′ may be formed on the first electrode 151′. The intermediate layer 153′ may have an organic light-emitting layer. In one or more embodiments, the intermediate layer 153 may further include at least one of a hole injection layer, a hole transport layer, an electron transport layer, and/or an electron injection layer, in addition to the organic light-emitting layer.

A second electrode 152′ may be formed on the intermediate layer 153′. The second electrode 152′ may be formed on the intermediate layer 153′.

An encapsulation member 170′ may be provided on the display element 150′ to protect the display element 150′.

In one or more embodiments, the display panel 10 may further include an optical functional layer 110′. The optical functional layer 110′ may include a layer for improving, changing, and variously selecting or controlling characteristics of light emitted by (realized in) the display element 150′.

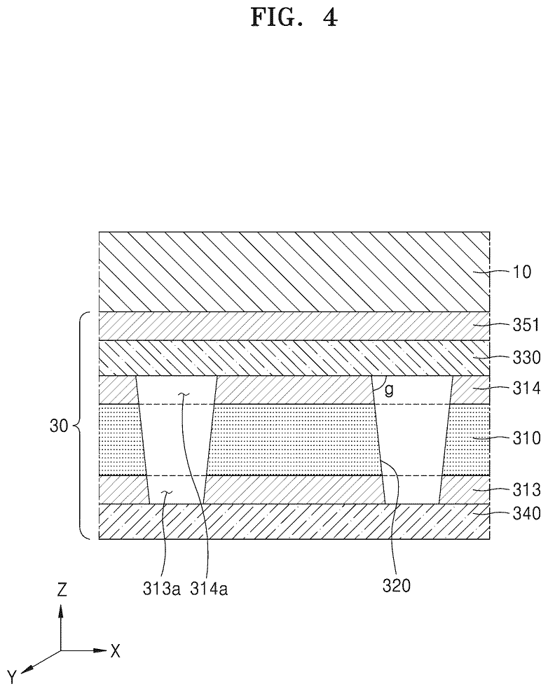

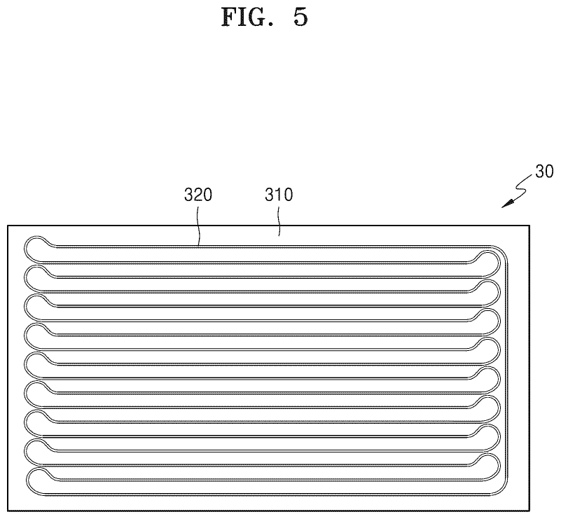

FIG. 4 is a cross-sectional view schematically illustrating an example of the display apparatus of FIG. 1, and FIG. 5 is a cross-sectional view schematically illustrating an example of a cross-section taken along the line I-I′ of FIG. 1.

Referring to FIG. 4, the heat dissipation member 30 may include a cover 340, a first adhesive layer 313, a base sheet 310, a second adhesive layer 314, a groove 320, and a plate 330.

The plate 330 of the heat dissipation member 30 may be coupled or bonded to the display panel 10 by a third adhesive layer 351.

The base sheet 310 may be a layer located between the cover 340 and the plate 330. The base sheet 310 may be coupled or bonded to the cover 340 by the first adhesive layer 313, and may be coupled or bonded to the plate 330 by the second adhesive layer 314.

In one or more embodiments, first adhesive layer 313, second adhesive layer 314, and third adhesive layer 351, may each include a thermal adhesive. The thermal adhesive may have high thermal conductivity and may include a polymer, an epoxy and/or the like.

The base sheet 310 may have one or more suitable shapes, for example, may have a plate shape corresponding to the display panel 10, and as an example, may be in the form of a sheet having an area corresponding to the display panel 10. As another example, the base sheet 310 may be formed smaller than the display panel 10, or as another example, may be formed larger than the display panel 10.

As an example, the base sheet 310 may have a thickness (Z-axis direction in FIG. 4) and a width and a length in a direction perpendicular to the thickness, and the width and length may have values greater than at least the thickness.

In one or more embodiments, as an example, the base sheet 310 may have a polygonal planar shape, and as an example, may have a rectangular planar shape.

The base sheet 310 may include a groove 320 that may serve as a (e.g., fluid) passage for refrigerant to flow. As an example, the groove 320 may be formed through cutting die design in the base sheet 310.

The base sheet 310 may be formed of a material with high thermal conductivity to absorb heat of the display panel 10 sufficiently (e.g., well).

In one or more embodiments, the base sheet 310 may be formed of a flexible material to improve coupling or bonding accuracy when the heat dissipation member 30 and the display panel 10 are coupled or bonded to each other. In one or more embodiments, when the heat dissipation member 30 and the display panel 10 are coupled or bonded through a roll-lamination process, the formation of the base sheet 310 using the flexible material may result in enhancing or improving the quality of an adhesion surface between the heat dissipation member 30 and the display panel 10, and reducing or suppressing the risk of plastic deformation due to impact on the heat dissipation member 30 and concentrated load on a wall between passages during the

The base sheet 310 may be formed of one or more suitable materials, and as an example, the materials of the base sheet 310 may include at least a polymer. This can allow passages to be more freely machined, formed, and changed in the base sheet 310 than in the base sheet 310 made of a metal material.

The base sheet 310 should have a thickness of a certain value or more so that refrigerant can flow into the groove 320 to have a heat dissipation effect, but the display apparatus 1 should be as thin as possible. As an example of satisfying the preceding conditions, the thickness of the base sheet 310 may be equal to and greater than 0.2 micrometer (μm) and less than 0.4 μm.

The groove 320 may be provided on the base sheet 310 and may be formed to have at least one path. For example, the groove 320 may form a closed loop as one path. Additionally, as an optional embodiment, the groove 320 may form a plurality of closed loops. As an optional embodiment, the groove 320 may be formed using a punching process, and the same passage or a plurality of passages may be designed by controlling an area for punching the groove 320 in the base sheet 310.

The groove 320 may be a passage along which at least a fluid flows. As an example, the groove 320 may be a passage along which refrigerant flows for heat dissipation. The refrigerant within the groove 320 may absorb heat generated from the display panel 10 and lower the temperature of the display panel 10.

One or more suitable types (kinds) of refrigerants may flow in the groove 320 of the closed loop. For example, gaseous or liquid refrigerant may flow in the groove 320.

As an example, refrigerant that is a mixture of two phases (e.g., of liquid and gas) may flow in the groove 320. When a certain portion of the display panel 10 is heated, refrigerant in the groove 320 overlapping the heated portion of the display panel 10 can absorb the heat of the display panel 10, and a certain amount of liquid refrigerant in the corresponding portion may phase change (e.g., vaporize or be transitioned) into gaseous refrigerant. For example, the refrigerant within the groove 320 of the closed loop may flow faster and absorb the heat of the display panel 10 more quickly.

Additionally, the groove 320 may be formed in the base sheet 310 to have a desired length and shape to control the length and area of the passage through which refrigerant flows.

As an example, the groove 320 may have a structure formed by repeating more than once, for example, a plurality of times, a process, in which the groove 320 is formed long in the base sheet 310 in one direction, for example, in a direction parallel to one side of the base sheet 310, and a direction is switched to form the groove 320 long in the direction parallel to the one side of the base sheet 310 again.

In one or more embodiments, the groove 320 may be formed from near (proximal to) one vertex of the base sheet 310 along one side (X-axis or Y-axis in FIG. 1) adjacent to the one vertex, and rotated by 180° toward an opposite vortex to the one vortex before reaching another side adjacent to the one side, to be formed up to a side, which is adjacent to the one vortex but different from the one side. In this manner, the groove 320 may be defined up to an opposite side to the one side. The groove 320 may form at least one (e.g., one or more) closed loops.

The groove 320 may be formed in one or more suitable ways, for example, through a process using a mold, and as an example, through a punching process using a cutting die (or blade die).

As described herein, the base sheet 310 may be formed of a flexible material to facilitate the punching process using the cutting die.

The groove 320 may be formed so that a width of a region farthest from (distal to) the display panel 10 is narrower than a width of a region closest (proximal) to the display panel 10 based on a thickness direction of the base sheet 310. For example, the groove 320 may be formed so that its width decreases away from the display panel 10 based on the thickness direction of the base sheet 310. Through this, when refrigerant (liquid or gas) for cooling the display panel 10 is in the groove 320, the refrigerant can be stable in the groove 320 and an area toward the display panel 10 can be increased, thereby improving heat dissipation efficiency.

The groove 320 may have a shape having (in which) a width that gradually decreases along a depth direction of the groove 320.

The groove 320 may have at least one inclined surface in at least one region of the base sheet 310. As an example, (e.g., two) inclined surfaces may be formed to correspond to inner surfaces of each (both) side(s) of the groove 320 so as to be opposite (face each other) in a width direction of the groove 320 (X-axis in FIG. 4). In one or more embodiments, the (e.g., two) inclined surfaces corresponding to the inner surfaces of each (both) side(s) of the groove 320 may have a symmetrical shape (e.g., be symmetrical to each other). For example, the inclined surfaces corresponding to the inner surfaces of both sides of the groove 320 may be symmetrical to each other with respect to the thickness direction of the base sheet 310 (e.g., Z-axis direction in FIG. 4).

In one or more embodiments, the inclined surfaces corresponding to the inner surfaces of both sides of the groove 320 may be asymmetrical with respect to the thickness direction of the base sheet 310 (e.g., Z-axis direction in FIG. 4).

In some embodiments, the inclined surfaces of the groove 320 may be curved at least once along the depth direction of the groove 320.

An angle formed between the groove 320 and the base sheet 310 may be less than 90°. An angle g formed between a top (e.g., second) surface of the base sheet 310 and the inner surface of the groove 320 may be less than 90°. For example, the angle g formed between an extension line of one surface, facing the display panel 10, among the surfaces of the base sheet 310 and the inner surface of the groove 320 may be less than 90°. For example, as illustrated in FIG. 4, when the second adhesive layer 314 is formed on the top (e.g., second) surface of the base sheet 310 and the second adhesive layer 314 is formed to have a side surface corresponding to the inner surface of the groove 320, the angle g formed between an extension line of one surface, facing the display panel 10, among surfaces of the second adhesive layer 314 and the inner surface of the groove 320 may be less than 90°.

As described herein, the groove 320 may be formed by the punching process using the mold or the cutting die. At this time, manufacturing characteristics using the cutting die can be improved by forming the angle between the groove 320 and the one surface of the base sheet 310 to be less than 90°. Thus, during the punching process using the cutting die, the cutting die can be easily removed from the base sheet 310.

A punching angle of the groove 320 can be adjusted to be less than 90°, so an area of a passage can be differentially designed merely by adjusting an inclination.

The groove 320 may be formed in one or more suitable shapes by using one or more suitable types (kinds) of cutting dies in the step of forming the groove 320. The groove 320 may be formed using one cutting die such that an angle between the base sheet 310 and one surface of the groove 320 is in the range of 50° to 80°. If the angle between the one surface of the groove 320 and the base sheet 310 is less than 50°, a small amount of fluid may be accommodated in the groove 320 and thereby a heat dissipation effect may be lowered. If the angle between the one surface of the groove 320 and the base sheet 310 exceeds 80°, it may be difficult to perform manufacturing using a cutting die and difficult to remove the cutting die from the base sheet 310 during the punching process using the cutting die.

The base sheet 310 may have a first surface and a second surface, and the second (e.g., top) surface may be opposite to (e.g., may face) the display panel 10. The cover 340 may have a surface opposite to the first surface of base sheet 310. In other words, the plate 330 may be bonded to an opposite surface to a surface, facing the cover 340, among surfaces of the base sheet 310. For example, the plate 330 may be provided to cover the base sheet 310 and the groove 320.

The plate 330 may be provided between the base sheet 310 and the display panel 10. The second adhesive layer 314 may be provided in at least one region between the plate 330 and the base sheet 310, and thus the plate 330 and the base sheet 310 can be bonded to each other by the second adhesive layer 314.

The second adhesive layer 314 may be provided to correspond to the periphery of the groove 320. In one or more embodiments, the second adhesive layer 314 may be formed to have a side surface corresponding to an inner surface (e.g., inclined surface) of the groove 320.

One region of the plate 330 may define a top surface of a passage through which refrigerant flows, and the second adhesive layer 314 may not be formed in this region. In other words, the second adhesive layer 314 may not be provided in a region corresponding to the uppermost portion in the depth direction among regions of the groove 320. For example, the second adhesive layer 314 may not be provided on one surface (upper surface in FIG. 4), facing the plate 330, among the regions of the groove 320.

Through this, when refrigerant as a fluid is accommodated in the groove 320, purity of the refrigerant can be maintained and refrigerant characteristics may be enhanced or improved, for example, the contact of the refrigerant with the second adhesive layer 314 may be prevented or reduced, thereby decreasing or suppressing deterioration of the refrigerant characteristics due to chemical reactions and other physical reactions with the second adhesive layer 314. In some embodiments, by reducing or suppressing impurities remaining in refrigerant, resistance to flow of the refrigerant can be reduced and the characteristics of the refrigerant flow may be enhanced or improved.

A third adhesive layer 351 may be provided in at least one region between the plate 330 and the display panel 10, and thus the plate 330 and the display panel 10 may be coupled or bonded to each other by the third adhesive layer 351. As an example, the plate 330 and the display panel 10 may be coupled or bonded using a

The plate 330 may have one or more suitable shapes. For example, the plate 330 may have a planar shape corresponding to the display panel 10, and as an example, may be formed in a planar shape having an area corresponding to the display panel 10. As another example, the plate 330 may be formed smaller than the display panel 10, or as another example, may be formed larger than the display panel 10.

As an example, the plate 330 may have a thickness (Z-axis direction in FIG. 4) and a width and a length in a direction perpendicular to the thickness, and the width and length may have values greater than at least the thickness.

Additionally, as an example, the plate 330 may have a shape of a polygonal plane, and as an example, may have a shape of a rectangular plane.

The plate 330 may be formed of a material with high thermal conductivity to absorb heat of the display panel 10 well. In some embodiments, the plate 330 may be formed of a flexible material to facilitate bonding with the display panel 10, for example, to facilitate lamination bonding, and may contain at least metal or graphite as an example. For example, if the material of the plate 330 is a metal, the production cost of the heat dissipation member 30 may be prevented or reduced.

The second adhesive layer 314 may be provided in at least one region between the base sheet 310 and the plate 330. The plate 330 and the base sheet 310 may be coupled or bonded to each other by the thermal adhesive of the second adhesive layer 314.

The second adhesive layer 314 may have a second spacing region 314a in a region corresponding to the groove 320. The second spacing region 314a may be in the form of a penetration region that is a region excluding (without) the thermal adhesive and/or the second adhesive layer 314.

Unlike a brazing or hot-melt method, in which a bonding material of the thermal adhesive and/or second adhesive layer 314 may remain in the groove 320 and thereby cause a chemical reaction with the refrigerant (e.g., and deteriorate the performance of the heat dissipation member when being physically removed), there is no remaining thermal adhesive and/or adhesive material on the region of the plate 330 defining the top surface of the passage by virtue of the second spacing region 314a. This can result in reducing resistance to the flow of the refrigerant and minimizing blockage of the refrigerant flow.

The thermal adhesive and/or the second adhesive layer 314 may have high adhesiveness so that the base sheet 310 and the plate 330 adhere well to each other, and may have water resistance to suppress external foreign substances such as moisture from penetrating into the passage. In some embodiments, the second adhesive layer 314 includes the thermal adhesive that may be made of a material with high thermal conductivity to effectively receive heat emitted from the display panel 10.

A third adhesive layer 351 may be provided in at least one region between the plate 330 and the display panel 10. The plate 330 and the display panel 10 may be bonded to each other by the thermal adhesive of the third adhesive layer 351.

In some embodiments, the third adhesive layer 351 includes the thermal adhesive that may be made of a material with high thermal conductivity to effectively receive heat emitted from the display panel 10.

The cover 340 may be provided to face a (e.g., first) surface of the base sheet 310, which is opposite to a (e.g., second) surface facing the display panel 10. In detail, the first adhesive layer 313 may be provided in at least one region between the base sheet 310 and the cover 340.

The cover 340 and the base sheet 310 may be coupled or bonded to each other by the thermal adhesive of the first adhesive layer 313.

The cover 340 is the outermost layer of the heat dissipation member 30, and must have a minimum thickness to withstand an external impact, but the thickness of the display apparatus 1 must be as thin as possible. As an example of satisfying the conditions, the thickness of the cover 340 may be equal to or greater than 0.1 μm and less than 0.5 μm.

The first adhesive layer 313 may be provided in at least one region between the base sheet 310 and the cover 340. The cover 340 and the base sheet 310 may be coupled or bonded to each other by the thermal adhesive of the first adhesive layer 313.

The first adhesive layer 313 may have a first spacing region 313a in a region corresponding to the groove 320. The first spacing region 313a may be in the form of a penetration region that is a region excluding (without) the thermal adhesive and/or the first adhesive layer 313.

The presence of the first spacing region 313a may provide an effect of reducing the chemical reaction of a remaining bonding material of the thermal adhesive and/or the first adhesive layer 313 with refrigerant in the groove 320 and deterioration of performance of the heat dissipation member caused when the remaining bonding material is physically removed.

In other words, thermal adhesive and/or the first adhesive layer 313 may not be provided in a region, corresponding to a bottom portion in the depth direction, among the regions of the groove 320. For example, the thermal adhesive and/or the first adhesive layer 313 may not be provided on one surface (lower surface in FIG. 4), facing the cover 340, among the regions of the groove 320.

Through this, when refrigerant as a fluid is accommodated in the groove 320, purity of the refrigerant can be maintained and refrigerant characteristics can be improved, for example, the contact of the refrigerant with the thermal adhesive and/or the first adhesive layer 313 may be prevented or reduced, thereby decreasing or suppressing deterioration of the refrigerant characteristics due to chemical reactions and other physical reactions with the thermal adhesive and/or the first adhesive layer 313. In some embodiments, by reducing or suppressing impurities remaining in refrigerant, resistance to flow of the refrigerant may be reduced and the characteristics of the refrigerant flow may be enhanced or improved.

The thermal adhesive and/or the first adhesive layer 313 may have high adhesiveness so that the base sheet 310 and the plate 330 adhere well to each other, and may have water resistance to suppress external foreign substances such as moisture from penetrating into the passage. In some embodiments, the first adhesive layer 313 includes the thermal adhesive that may be made of a material with high thermal conductivity to effectively receive heat emitted from the display panel 10.

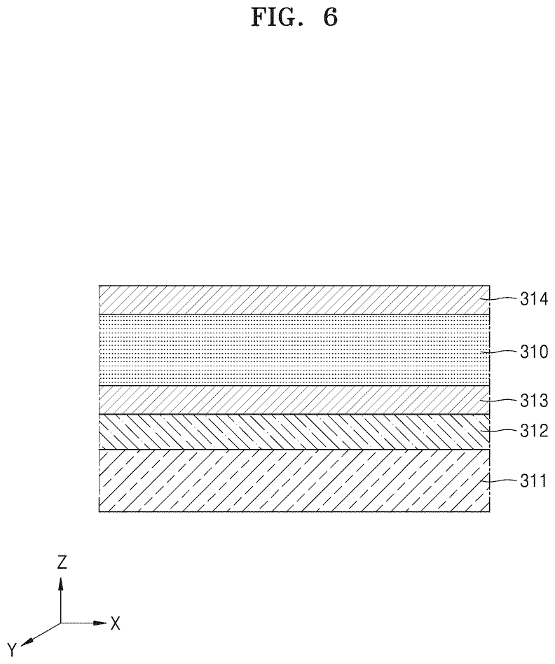

FIGS. 6 to 12 are cross-sectional views, each illustrating an example of a method for manufacturing a display apparatus according to one or more embodiments of the present disclosure.

For example, FIGS. 6 to 11 are drawings of examples for explaining the process of manufacturing the display apparatus 1 of FIG. 1. This is for convenience of explanation, and the manufacturing method according to one or more embodiments of the present disclosure may be applicable to display apparatus(es) according to other embodiments in the same manner or by being modified within a similar range as needed.

For convenience of explanation, the heat dissipation member 30 of FIG. 1 will be explained in more detail as an example herein.

First, referring to FIG. 6, a first release paper 312 may be stacked on a support member 311, the first adhesive layer 313 on the first release paper 312, the base sheet 310 on the first adhesive layer 313, and the second adhesive layer 314 on the base sheet 310. For example, a basic core structure of the heat dissipation member 30 may be provided or prepared.

The support member 311 may be made of metal, as an example. The metal support member 311 can be recycled, thereby reducing the production cost of the display apparatus 1.

The support member 311 and the first release paper 312 may be coupled or bonded by different adhesive layers, as an example.

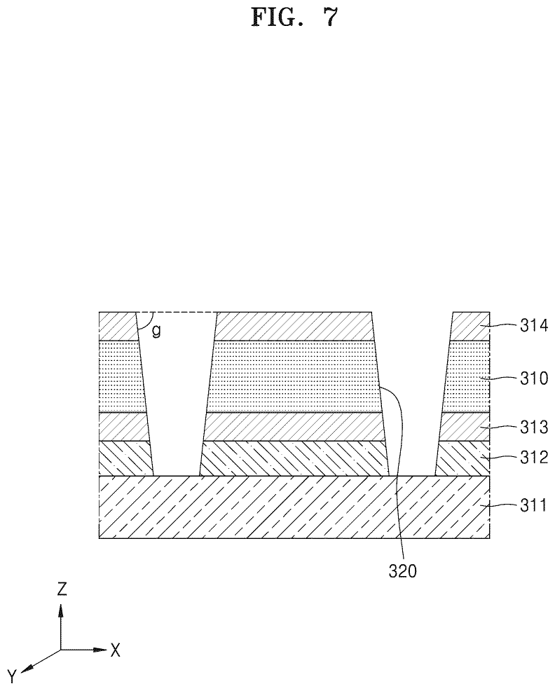

Referring to FIG. 7, the groove 320 that can form at least one passage may be formed in the first adhesive layer 313, the base sheet 310, and the second adhesive layer 314.

The groove 320 may be formed on the surface of the base sheet 310 through a process using a mold. The groove 320 may be formed in the base sheet 310 such that at least a fluid can flow, and may be formed to have a region in which the width of a region farthest from (distal) the display panel 10 is narrower than the width of a region closest to (proximal) the display panel 10 based on the thickness direction of the base sheet 310. In this instance, the groove 320 may be formed through a process using a mold, as an optional example, through a punching process using a cutting die.

A punching process may be performed by applying pressure to the cutting die at least once in a direction that the cutting die comes in contact with the base sheet 310, thereby forming the groove 320. As an optional embodiment, a cutting die which has a shape corresponding to a closed loop-shaped groove 320 having one or more curves may be prepared, and a punching process of applying pressure to the base sheet 310 using the cutting die may be performed one time, thereby implementing the shape of the groove 320.

When this punching process is performed, a depth to punch (punching depth of) the groove 320 can be selected or controlled, so that the groove 320 may be formed up to the first release paper 312. In this step, the passage may be punched and formed.

When forming the groove 320, the support member 311 can fix the first release paper 312, the first adhesive layer 313, the base sheet 310, and the second adhesive layer 314 formed thereon, suppress the walls and each layer of the groove 320 from being bent or moved, and allow the formation of a narrow passage.

The base sheet 310 may be made of a flexible material to facilitate the punching of the groove 320. The base sheet 310 may be formed of one or more suitable materials, and examples of such materials may include at least a polymer.

The groove 320 may be punched in a desired length and shape to control length and area of the passage through which refrigerant flows. As an example, the groove 320 may be formed through punching using a cutting die design. The width and area of the passage, the number of passages, and/or the like may be adjusted by selecting or controlling a punching width and a punching angle.

In some embodiments, the groove 320 may be formed through the punching using the cutting die design, so that the width of a region farthest from (distal) the display panel 10 is narrower than the width of a region closest to (proximal) the display panel 10 based on the thickness direction of the base sheet 310. For example, the groove 320 may be formed so that its width decreases away from (distal) the display panel 10 based on the thickness direction of the base sheet 310. Through this, when refrigerant (liquid and/or gas) for cooling the display panel 10 is in the groove 320, the refrigerant can be stable in the groove 320 and an area toward the display panel 10 can be increased, thereby enhancing or improving heat dissipation efficiency.

The groove 320 may be formed through punching to have an inclined surface in at least one region of the base sheet 310. As an example, inclined surfaces may be formed to correspond to inner surfaces of both sides of the groove 320 to be opposite (face) each other in a width direction of the groove 320 (X-axis in FIG. 7). In some embodiments, the inclined surfaces corresponding to the inner surfaces of both sides of the groove 320 may be symmetrical to each other. For example, the inclined surfaces corresponding to the inner surfaces of both sides of the groove 320 may be symmetrical to each other with respect to the thickness direction of the base sheet 310 (e.g., Z-axis direction in FIG. 7).

In some embodiments, the inclined surfaces corresponding to the inner surfaces of both sides of the groove 320 may be asymmetrical with respect to the thickness direction of the base sheet 310 (e.g., Z-axis direction in FIG. 7).

Additionally, one or more curves may be formed along the depth direction of the groove 320.

An angle formed between the groove 320 and one surface of the base sheet 310 may be less than 90°. An angle g formed by the top surface of the base sheet 310 and the inner surface of the groove 320 may be less than 90°. For example, the angle g formed between an extension line of one surface, facing the display panel 10, among surfaces of the base sheet 310 and the inner surface of the groove 320 may be less than 90°. As an optional embodiment, when the second adhesive layer 314 is formed on the top (second) surface of the base sheet 310 to have a side surface corresponding to the inner surface of the groove 320, the angle g formed between an extension line of one surface, facing the display panel 10, among surfaces of the second adhesive layer 314 and the inner surface of the groove 320 may be less than 90°.

The groove 320 may be formed by a punching process using a mold or a cutting die. At this time, cutting die manufacturing characteristics can be improved by forming the angle between the groove 320 and the one surface of the base sheet 310 to be less than 90°. Thus, during the punching process using the cutting die, the cutting die can be easily removed from the base sheet 310.

The groove 320 may be formed in one or more suitable shapes by using one or more suitable types (kinds) of cutting dies in the step of forming the groove 320. The groove 320 may be formed using one cutting die such that an angle between the base sheet 310 and one surface of the groove 320 is in the range of 50° to 80°. If the angle between the one surface of the groove 320 and the base sheet 310 is less than 50°, a small amount of fluid may be accommodated in the groove 320 and thereby a heat dissipation effect may be lowered. If the angle between the one surface of the groove 320 and the base sheet 310 exceeds 80°, it may be difficult to perform manufacturing using a cutting die and difficult to remove the cutting die from the base sheet 310 during the punching process using the cutting die.

As an example, the groove 320 may be formed by repeating more than once, for example, a plurality of times, a punching process, in which the groove 320 is formed long in one direction of the base sheet 310, for example, in a direction parallel to one side of the base sheet 310, and a direction is switched to form the groove 320 long in the direction parallel to the one side of the base sheet 310 again. In some embodiments, the cutting die for performing the punching process, as described herein, may be prepared in advance to correspond to the overall shape of the groove 320, so that the shape of the groove 320 can be implemented through a single punching process.

In some embodiments, the groove 320 may be formed from near one vertex of the base sheet 310 along one side (X-axis or Y-axis in FIG. 1) adjacent to the one vertex, and rotated by 180° toward an opposite vortex to the one vortex before reaching another side adjacent to the one side, to be formed up to a side, which is adjacent to the one vortex but different from the one side. In this manner, the groove 320 may be punched up to an opposite side to the one side. The groove 320 may form one or more closed loops.

When forming the groove 320, the first adhesive layer 313 and the second adhesive layer 314, which are portions corresponding to bottom and top surfaces of the passage may also be punched, thereby reducing an area by which refrigerant flowing along the passage is in contact with the thermal adhesive and/or an adhesive agent.

Accordingly, the second adhesive layer 314 may not be formed in one region of the plate 330 which may define the top surface of the passage through which refrigerant flows. In other words, the thermal adhesive and/or the second adhesive layer 314 may not be provided in a region, corresponding to the uppermost portion in the depth direction, among the regions of the groove 320. For example, the thermal adhesive and/or the second adhesive layer 314 may not be provided on one surface (upper surface in FIG. 7), facing the plate 330, among the regions of the groove 320.

The second adhesive layer 314 may have a second spacing region 314a defined in a region corresponding to the groove 320. The second spacing region 314a may be in the form of a penetration region that is a region without the second adhesive layer 314.

In some embodiments, the first adhesive layer 313 may not be formed in one region of the cover 340 which may define the bottom surface of the passage through which refrigerant flows. In other words, the thermal adhesive and/or the first adhesive layer 313 may not be provided in a region, corresponding to the lowermost portion in the depth direction, among the regions of the groove 320. For example, the thermal adhesive and/or the first adhesive layer 313 may not be provided on one surface (lower surface in FIG. 7), facing the cover 340, among the regions of the groove 320.

The first adhesive layer 313 may have a first spacing region 313a defined in a region corresponding to the groove 320. The first spacing region 313a may be in the form of a penetration region that is a region excluding (without) the thermal adhesive of the first adhesive layer 313.

Through the preceding description, when refrigerant as a fluid is accommodated in the groove 320, the purity of the refrigerant may be maintained and refrigerant characteristics may be enhanced or improved, for example, the contact of the refrigerant with the thermal adhesive of the first adhesive layer 313 and the second adhesive layer 314 may be prevented or reduced, thereby decreasing or suppressing deterioration of the refrigerant characteristics due to chemical reactions and other physical reactions with the thermal adhesive of the first adhesive layer 313 and the second adhesive layer 314. In some embodiments, by reducing or suppressing impurities introduced or remaining in refrigerant, resistance to flow of the refrigerant may be prevented or reduced and the characteristics of the refrigerant flow may be enhanced or improved.

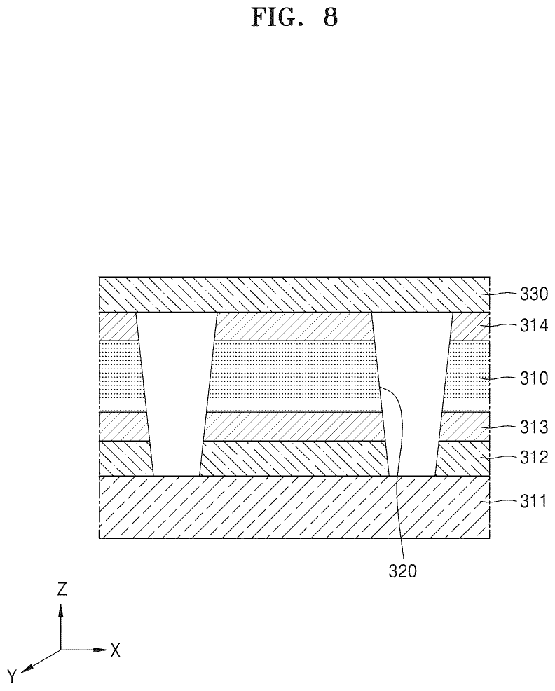

Referring to FIG. 8, after forming the groove 320 that may define the passage, the plate 330 may be stacked on the second adhesive layer 314. For example, this step may be a step of attaching the plate 330. As the plate 330 is attached, the passage may be provided or generated.

One region of the plate 330 may define the top surface of the passage through which refrigerant flows. The second adhesive layer 314 may be removed from the region through punching, thereby avoiding (improving the problem of) deteriorating the performance of the heat dissipation member caused when a remaining bonding material chemically reacts with refrigerant and is physically removed.

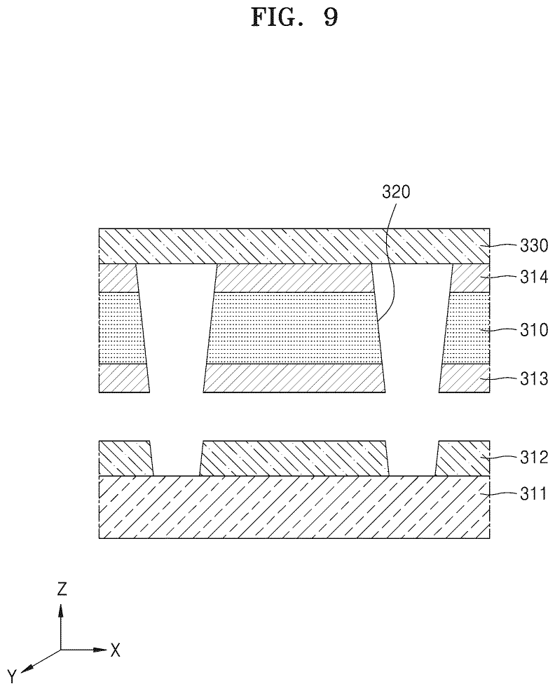

Referring to FIG. 9, after attaching the plate 330, the first release paper 312 and the support member 311 on the opposite side of the plate 330 may be removed.

The first release paper 312 may be a layer whose surface is treated to protect an adhesive surface and to be easily removed from the support member 311.

The support member 311 may be made of a metal material and may be recycled because the groove 320 is not punched therein.

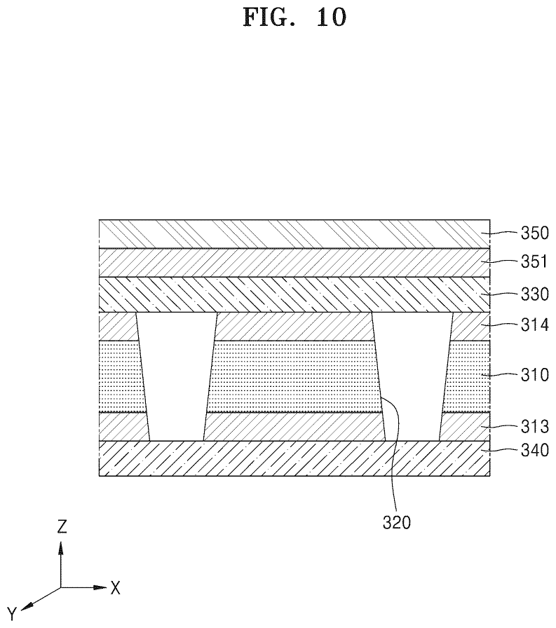

Referring to FIG. 10, after the first release paper 312 and the support member 311 are removed, the cover 340 and the third adhesive layer 351 may be attached, and a second release paper 350 may be attached on the third adhesive layer 351. In this step, the heat dissipation member 30 may be provided or commercialized by attaching the cover 340 and the third adhesive layer 351.

The cover 340 may be attached to the surface of the first adhesive layer 313 from which the first release paper 312 and the support member 311 have been removed.

One region of the cover 340 may define the bottom surface of the passage through which refrigerant flows. The first adhesive layer 313 may be removed from the region through punching, thereby avoiding (improving the problem of) deteriorating the performance of the heat dissipation member caused when a remaining bonding material chemically reacts with refrigerant and is physically removed.

The third adhesive layer 351 may be stacked on the plate 330, and the second release paper 350 may be stacked on the third adhesive layer 351. The third adhesive layer 351 may be a layer by which the heat dissipation member 30, for example, the plate 330 is bonded to the display panel 10. The second release paper 350 may maintain and protect the adhesive strength of the third adhesive layer 351 and may be easily removed so that the display panel 10 and the third adhesive layer 351 may be coupled or bonded to each other.

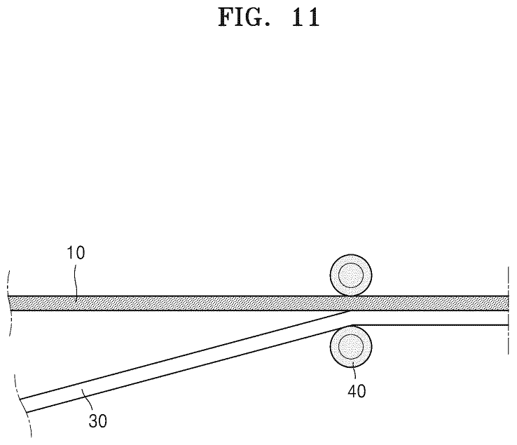

Referring to FIG. 11, the attachment of the display panel 10 and the heat dissipation member 30 is illustrated. The heat dissipation member according to another embodiment may be applied to the method of manufacturing the display apparatus according to one or more embodiments of the present disclosure in substantially the same manner or by being modified within a similar range as needed.

The display panel 10 and the heat dissipation member 30 may be provided or prepared separately and coupled or attached to each other. However, before attaching the display panel 10 and the heat dissipation member 30, the second release paper 350 on the third adhesive layer 351 of the heat dissipation member 30 may be removed.

The attachment of the display panel 10 and the heat dissipation member 30 may be provided or performed using one or more suitable methods. As an example, the display panel 10 as a flat panel and the heat dissipation member 30 may be coupled or bonded by a roll-lamination process in which two layers are pressed to be coupled or bonded to each other by a pair of rolls 40.

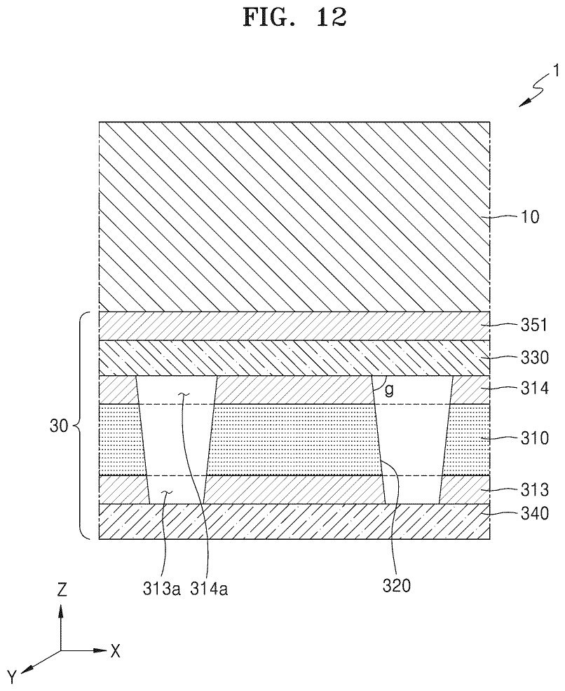

Through the coupling or bonding process of the display panel 10 and the heat dissipation member 30, the display apparatus 1 as illustrated in FIG. 12 can be manufactured.

In the manufacturing method according to one or more embodiments, the display apparatus 1 may be easily manufactured by easily attaching the display panel 10 and the heat dissipation member 30, and as an example, the display apparatus 1 with a large size may be efficiently manufactured.

Referring to FIG. 12, in the one example of the display apparatus 1 manufactured through the steps of FIGS. 6 to 11, the heat dissipation member 30 may be provided on one surface of the display panel 10, one surface of the plate 330 of the heat dissipation member 30 may be adhered to the one surface of the display panel 10 by the third adhesive layer 351, and another surface of the plate 330 may be adhered to one surface (second surface) of the base sheet 310 by the second adhesive layer 314 between the plate 330 and the base sheet 310. Another surface (first surface) of the base sheet 310 may be adhered to the cover 340 by the first adhesive layer 313 between the base sheet 310 and the cover 340. Additionally, the groove 320 may be formed in the first adhesive layer 313, the base sheet 310, and the second adhesive layer 314 to form an angle of less than 90° with the surface of each layer.

In the one example of the display apparatus 1 manufactured through the steps, the heat dissipation member 30 may be provided on one surface of the display panel 10, one surface of the plate 330 of the heat dissipation member 30 may be adhered to the one surface of the display panel 10 by the third adhesive layer 351, and another surface of the plate 330 may be adhered to one surface (second surface) of the base sheet 310 by the second adhesive layer 314 between the plate 330 and the base sheet 310. Another surface of the base sheet 310 (first surface) may be adhered to the cover 340 by the first adhesive layer 313 between the base sheet 310 and the cover 340. Additionally, the groove 320 may be provided or formed in the first adhesive layer 313, the base sheet 310, and the second adhesive layer 314 to form an angle, which is equal to or smaller than 90°, with the surface of each layer.

For example, the heat dissipation member 30 in one or more embodiments of the present disclosure may be configured as a three-layer structure in which the plate 330 and the cover 340 are provided respectively on one surface and another surface of the polymer base sheet 310 in which the passage is formed. In some embodiments, since the plate 330 may be made of a graphite material, the heat dissipation member 30 may have a composite structure of a pulsating heat pipe and a graphite layer, including the groove 320 forming the passage and the plate 330 as the graphite layer covering the groove 320.

In the display apparatus 1 having the herein-described structure through the preceding steps, the base sheet 310 may be made of the polymer material, which may improve or facilitate coupling or bonding of the heat dissipation member 30 and the display panel 10, and the plate 330 which may be made of a metal material and the metal support member 311 may reduce production costs and ensure structural stability of the display apparatus 1.

The plate 330 and the cover 340 in one region, which defines the bottom surface and the top surface of the passage through which refrigerant flows, may be spaced and/or apart (e.g., spaced apart or separated) from each other without interposing the second adhesive layer 314 and the first adhesive layer 313 therebetween. Accordingly, a contact area between the refrigerant and a remaining adhesive material may be reduced while the refrigerant flows in the passage, resulting in reducing resistance to the flow of the refrigerant and avoiding or alleviating blockage of the passage.

The method of forming the groove 320 using the cutting die (blade die) may improve or facilitate the machining and forming of the shape of the passage. In some embodiments, the display apparatus 1 with an improved heat dissipation effect may be provided by forming the passage, through which refrigerant flows, in a manner of selecting or controlling a punching angle, depth, and width of the groove 320.

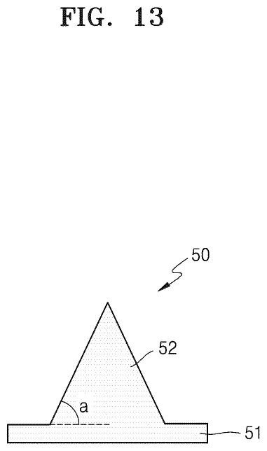

FIG. 13 is a cross-sectional view schematically illustrating an example of a cutting die used in manufacturing a display apparatus according to one or more embodiments.

When forming the passage through which refrigerant flows through punching, the groove 320 may be formed using one or more suitable cutting dies. Depending on the type (kind) of cutting die, an angle formed with the base sheet 310 for each passage section may vary, and one or more suitable passage shapes and widths may be implemented.

For example, as an angle between a blade of a cutting die 50 and a plate supporting the blade is closer to 90°, an angle between the formed passage, that is, the groove 320 and the base sheet 310 may also be closer to 90°.

FIG. 13 illustrates an example of a cutting die used when forming a passage in the example heat dissipation member 30. The groove 320 of FIG. 12 may be formed using the cutting die 50.

The cutting die 50 may include a flat portion 51 and a protruding portion 52 which may be a blade. The flat portion 51 may serve as a substrate to which the protruding portion 52 (blade) is attached.

The protruding portion 52 may be symmetrically pointed around the center of the protruding portion 52 to form a passage with the blade. The protruding portion 52 may extend from the flat portion 51 to form an inclined plane with respect to the flat portion 51, and an angle a formed between the inclined plane and the flat portion 51 may range from 50° to 70°.

The groove 320 manufactured by the cutting die 50 may form an angle g, which is formed between the upper surface (second surface) of the base sheet 310 and the inclined surface of the groove 320 to correspond to the angle a formed between the protruding portion 52 and the flat portion 51 of the cutting die 50. The angle a formed between the protruding portion 52 and the flat portion 51 of the cutting die 50 may range from 50° to 70°, and the angle g formed between the upper surface (second surface) of the base sheet 310 and the inclined surface of the groove 320 may range from 50° to 70°.

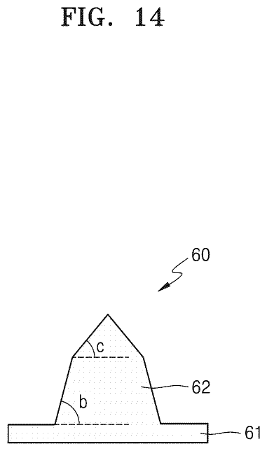

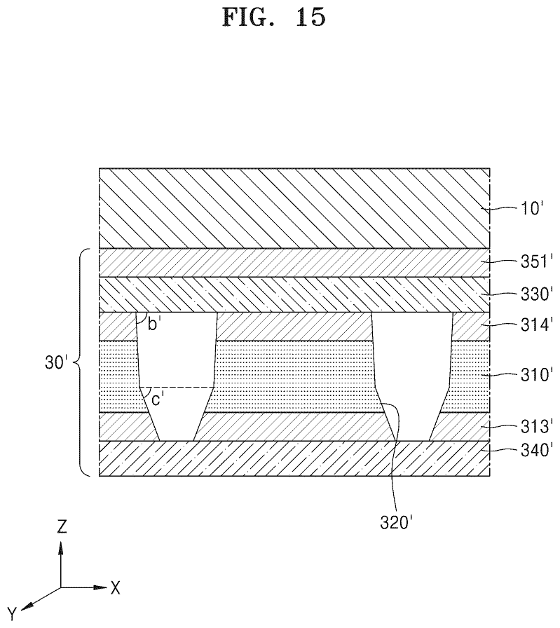

FIG. 14 is a cross-sectional view illustrating an example of a cutting die used in manufacturing a display apparatus according to one or more embodiments, and FIG. 15 is a cross-sectional view illustrating an example of a display apparatus manufactured using the cutting die of FIG. 14.

FIG. 14 illustrates another example of a cutting die used when forming a passage in a heat dissipation member 30′ according to one or more embodiments. A groove 320′ of FIG. 15 may be formed using a cutting die 60.

The cutting die 60 may include a flat portion 61 and a protruding portion 62 which may be a blade. The flat portion 61 may serve as a substrate to which a protruding portion 62 (blade) is attached.

The protruding portion 62 may be symmetrically pointed around the center of the protruding portion 62 to form a passage with the blade. The protruding portion 62 may be symmetrically pointed around the center of the protruding portion 62 to form a passage with the blade.

The inclined surface of the blade may extend from the flat portion 61 to form a first angle b with the flat portion 61, and the extended inclined surface may then be bent to form a second angle c with the flat portion 61. The first angle b may be an angle in the range of 83° to 90°, and the second angle c may be an angle in the range of 62.5° to 75°.

The groove 320′ manufactured by the cutting die 60 may form an angle b′ between an upper surface (second surface) of a base sheet 310′ and the inclined surface of the groove 320′, corresponding to the first angle b formed between the protruding portion 62 and the flat portion 61 of the cutting die 60, and may form an angle c′ between an upper surface of a cover 340′ and a surface of the groove 320′ in contact with the cover 340′, corresponding to the second angle c formed between the inclined surface bent at the protruding portion 62 of the cutting die 60 and the flat portion 61.

The first angle b of the cutting die 60 may be in the range of 83° to 90°, the second angle c may be in the range of 62.5° to 75°, the angle b′ between the upper surface of the base sheet 310′ and the inclined surface of the groove 320′ may be in the range of 83° to 90°, and the angle c′ between the upper surface of the cover 340′ and the surface of the groove 320′ in contact with the cover 340′ may be in the range of 83° to 90°.

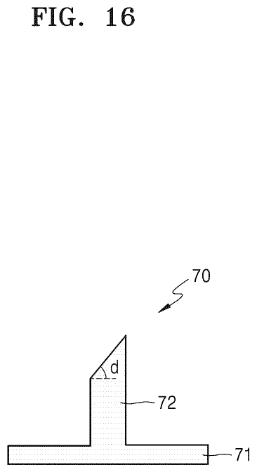

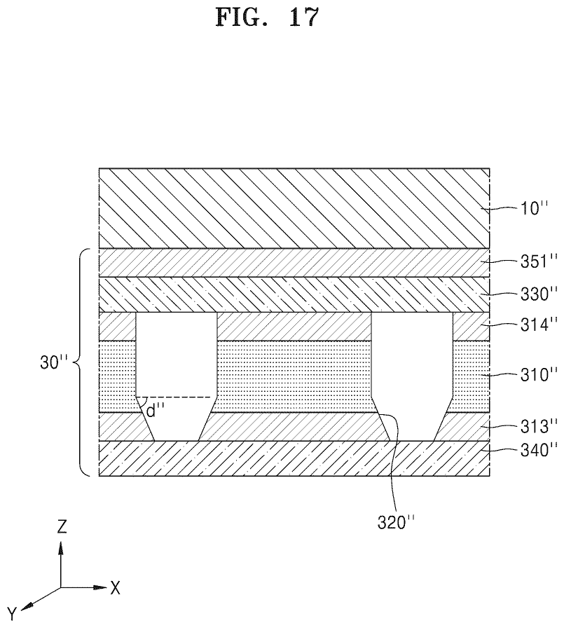

FIG. 16 is a cross-sectional view illustrating an example of a cutting die used in manufacturing a display apparatus according to one or more embodiments, and FIG. 17 is a cross-sectional view illustrating an example of a display apparatus manufactured using the cutting die of FIG. 16.

FIG. 16 illustrates another example of a cutting die used when forming a passage in a heat dissipation member 30″ according to one or more embodiments. The groove 320″ of FIG. 17 may be formed using a cutting die 70.

The cutting die 70 may include a flat portion 71 and a protruding portion 72 which may be a blade. The flat portion 71 may serve as a substrate to which a protruding portion 72 (blade) is attached.

The protruding portion 72 may include two sides extending at an angle of 90° from the flat portion 71 to form a passage with a blade. The two sides may have different lengths and their ends may be connected by a straight line.

An angle d between the flat portion 71 and a line connecting the ends of the two sides, which extend from the flat portion 71, may be in the range of 70° to 80°.

The groove 320″ manufactured by the cutting die 70 may form an angle d″ between an upper surface of a cover 340″ and a surface of the groove 320″ in contact with the cover 340″, corresponding to the angle d between the flat portion 71 and an inclined surface defined by the line connecting the ends of the two sides of the protruding portion 72, which extend from the flat portion 71.

The angle d between the flat portion 71 and the line connecting the ends of the two sides extending from the flat portion 71 of the cutting die 70 may be in the range of 70° to 80°, and the angle d″ between the upper surface of the cover 340″ and the surface of the groove 320″ in contact with the cover 340″ may be in the range of 70° to 80°.

The display apparatus 1 may further include a housing which accommodates the display panel 10 and a heat dissipation member 30. For example, the heat dissipation member 30 may be placed between the housing and the display panel 10.

The display apparatus 1 according to one or more embodiments may be applied to one or more suitable electronic devices 1000. An electronic device 1000 according to one or more embodiments may include the display apparatus 1 described herein, and may further include a module or device having additional functions, in addition to the display apparatus 1.

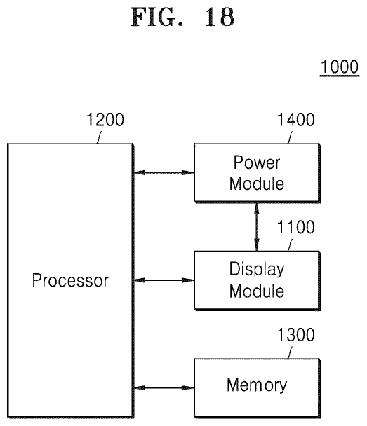

FIG. 18 is a block diagram of an electronic device according to one or more embodiments. Referring to FIG. 18, an electronic device 1000 according to one or more embodiments may include a display module 1100, a processor 1200, a memory 1300, and a power module 1400.

The processor 1200 may include at least one of a central processing unit (CPU), an application processor (AP), a graphics processing unit (GPU), a communication processor (CP), an image signal processor (ISP), or a controller.

The memory 1300 may store data information required for operation of the processor 1200 or the display module 1100. An image data signal and/or an input control signal may be transmitted to the display module 1100 in case that the processor 1200 executes an application stored in the memory 1300, and the display module 1100 may output image information through a display screen by processing the received signal.

The power module 1400 may include a power supply module, such as a power adapter or a battery device, and a power conversion module which converts power supplied by the power supply module to generate power required for the operation of the electronic device 1000.

At least one of respective components of the electronic device 1000 may be included in the display apparatus 1 according to one or more embodiments described herein. In some embodiments, some of the individual modules functionally included in a module may be included in a display apparatus, while others may be provided separately from the display apparatus. For example, the display apparatus 1 may include the display module 1100, and the processor 1200, the memory 1300, and the power module 1400 may be provided in the form of other apparatuses in the electronic device 1000 other than the display apparatus 1.

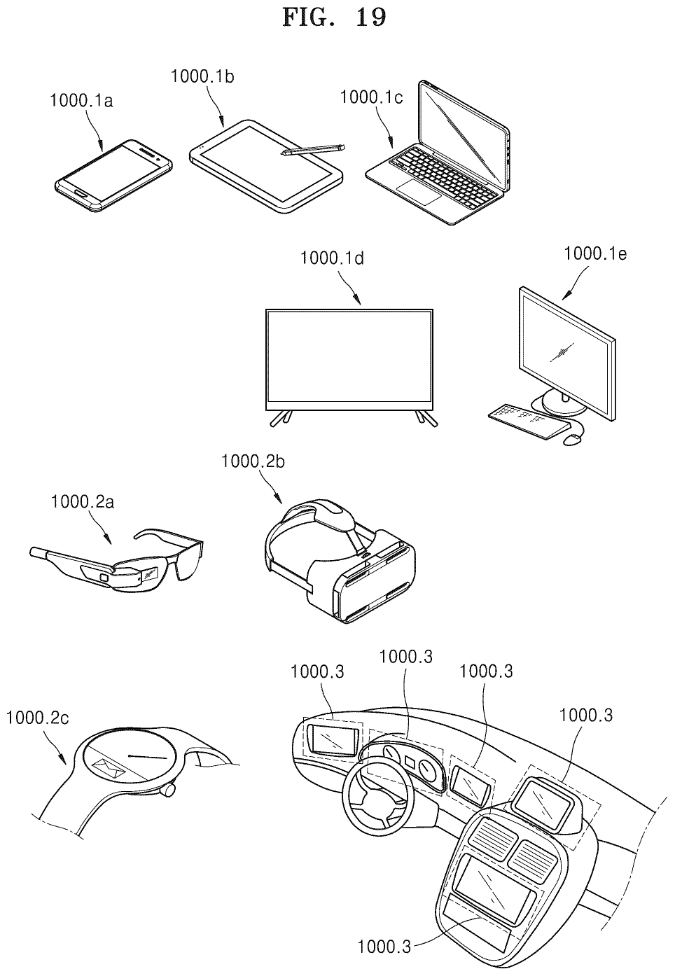

FIG. 19 illustrates schematic views of individual electronic devices according to one or more suitable embodiments.

Referring to FIG. 19, one or more suitable electronic devices according to embodiments, to which the display apparatus 1 is applied, may include: an electronic device for displaying an image, such as a smart phone 1000.1a, a tablet PC 1000.1b, a laptop computer 1000.1c, a TV set 1000.1d, a desk monitor 1000.1e, and/or the like; a wearable electronic device including a display module, such as smart glasses 1000.2a, a head mounted display 1000.2b, a smart watch 1000.2c, and/or the like; and an electronic device 1000.3 for vehicles including a display module, such as a center information display (CID) provided on an instrument panel, center fascia, or dashboard of a vehicle, a room mirror display, and/or the like.

Each of the embodiments described herein can be implemented independently, but of course, the structure of each embodiment can be applied in combination to other embodiments.

As such, the present disclosure has been described with reference to the embodiments shown in the drawings, but these are merely illustrative, and those skilled in the art will understand that one or more suitable modifications and equivalent other embodiments are possible therefrom. Therefore, the true scope of technical protection of the present disclosure should be determined by the technical spirit of the attached patent claims.

Specific implementations described in the embodiments are examples and do not limit the scope of the embodiments in any way. Additionally, if there is no specific mention such as “essential,” “important,” and/or the like, it may not be a necessary component for the application of the present disclosure.

The use of the term “above” and similar referential terms in the specification of the embodiment (especially in the claims) may refer to both the singular and the plural. In some embodiments, when a range is described in an example, the disclosure includes the application of individual values within the range (unless there is a statement to the contrary), and is the same as describing each individual value constituting the range in the detailed description. Finally, unless the order of the steps constituting the method according to the embodiments is clearly stated or there is no description to the contrary, the steps may be performed in an appropriate order. The embodiments are not necessarily limited by the order of description of the preceding steps. The use of all examples or illustrative terms in the embodiments is simply for explaining the embodiments in detail, and the scope of the embodiments is not limited by the examples or illustrative terms unless limited by the claims. Additionally, those skilled in the art will recognize that one or more suitable modifications, combinations and changes may be made depending on design conditions and factors within the scope of the appended claims or their equivalents.

The display apparatus, the method of manufacturing the same and the electronic device according to the embodiments of the present disclosure can improve manufacturing convenience and heat dissipation characteristics.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or ±30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

The display apparatus, electronic device, a device of manufacturing thereof, and/or any other relevant devices or components according to embodiments of the present disclosure described herein may be implemented utilizing any suitable hardware, firmware (e.g., an application-specific integrated circuit), software, or a combination of software, firmware, and hardware. For example, the one or more suitable components of the display apparatus and/or electronic device may be formed on one integrated circuit (IC) chip or on separate IC chips. Further, the one or more suitable components of the display apparatus and/or electronic device may be implemented on a flexible printed circuit film, a tape carrier package (TCP), a printed circuit board (PCB), or formed on one substrate. Further, the one or more suitable components of the display apparatus and/or electronic device may be a process or thread, running on one or more processors, in one or more computing devices, executing computer program instructions and interacting with other system components for performing the one or more suitable functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of one or more suitable computing devices may be combined or integrated into a single computing device, or the functionality of a particular computing device may be distributed across one or more other computing devices without departing from the scope of the embodiments of the present disclosure.

In the context of the present application and unless otherwise defined, the terms “use,” “using,” and “used” may be considered synonymous with the terms “utilize,” “utilizing,” and “utilized,” respectively.

It should be understood that one or more embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that one or more suitable changes in form and details may be made therein without departing from the spirit and scope as defined by the following claims, and equivalents thereof.

What is claimed is:

1. A display apparatus comprising:
a display panel configured to emit visible light; and
a heat dissipation member on a surface of the display panel, the heat dissipation member comprising:
a base sheet having a first surface and a second surface, the second surface being opposite to the surface of the display panel; and
a cover having a surface opposite to the first surface of the base sheet,
wherein a groove is in the base sheet, the groove being a fluid passage and having a first width region and a second width region,
wherein the first width region is distal to the display panel based on a thickness direction of the base sheet, and is more narrow than the second width region that is proximal to the display panel based on the thickness direction of the base sheet.

2. The display apparatus of claim 1, wherein the groove has a width decreasing along a depth direction of the groove.

3. The display apparatus of claim 1, wherein the groove has an inclined surface in at least one region of the base sheet.

4. The display apparatus of claim 3, wherein the groove has symmetrical inclined surfaces.

5. The display apparatus of claim 1, wherein an angle between an extension line of the second surface of the base sheet and an inner surface of the groove is equal to or less than 90 degrees (°).

6. The display apparatus of claim 1, wherein an angle between an extension line of the second surface of the base sheet and an inner surface of the groove is in a range from 50° to 80°.

7. The display apparatus of claim 1, wherein a first adhesive layer is in at least one region between the base sheet and the cover.

8. The display apparatus of claim 7, wherein the first adhesive layer comprises:
a thermal adhesive; and
a first spacing region in a region corresponding to the groove, the first spacing region excluding the thermal adhesive.

9. The display apparatus of claim 1, wherein a plate is coupled to the second surface of the base sheet.

10. The display apparatus of claim 9, wherein a second adhesive layer is in at least one region between the base sheet and the plate.

11. The display apparatus of claim 10, wherein the second adhesive layer comprises:
a thermal adhesive; and
a second spacing region in a region corresponding to the groove, the second spacing region excluding the thermal adhesive.

12. The display apparatus of claim 9, wherein a third adhesive layer is between the plate and the display panel.

13. The display apparatus of claim 1, wherein the base sheet comprises a flexible material.

14. The display apparatus of claim 1, wherein the base sheet comprises a polymer-based material.

15. The display apparatus of claim 1, wherein the display panel comprises an organic light-emitting element.

16. A method for manufacturing a display apparatus, the method comprising:
providing a display panel configured to emit visible light;
providing a heat dissipation member; and
coupling the display panel to the heat dissipation member,
the heat dissipation member comprising:
a base sheet having a first surface and a second surface, the second surface being opposite to a surface of the display panel; and
a cover having a surface opposite to the first surface,
wherein a groove in the base sheet, the groove being a fluid passage and having a first width region and a second width region,
wherein the first width region is distal to the display panel based on a thickness direction of the base sheet, and is more narrow than the second width region that is proximal to the display panel based on a thickness direction of the base sheet.

17. The method of claim 16, wherein the providing the heat dissipation member comprises forming the groove in the first surface and/or the second surface of the base sheet by using a mold.

18. The method of claim 17, wherein the mold comprises a cutting die for punching.

19. The method of claim 17, wherein the providing the heat dissipation member comprises:
forming adhesive layers on the first surface and the second surface of the base sheet; and
forming the groove by using the mold.

20. The method of claim 17, wherein the providing the heat dissipation member comprises adhering a plate after forming the groove.

21. An electronic device comprising:
a display module, a processor, a memory, and a power module,
the display module comprising:
a display panel configured to emit visible light; and
a heat dissipation member on a surface of the display panel, the heat dissipation member comprising:
a base sheet having a first surface and a second surface, the second surface being opposite to the surface of the display panel; and
a cover having a surface opposite to the first surface of the base sheet,
wherein a groove is in the base sheet, the groove being a fluid passage and having a first width region and a second width region,
wherein the first width region is distal to the display panel based on a thickness direction of the base sheet, and is more narrow than the second width region that is proximal to the display panel based on a thickness direction of the base sheet.
